(19) United States
(12) Patent Application Publication
(10) Pub. No.: US 2014/0182511 A1
(43) Pub. Date: Jul. 3, 2014

(54) PROTECTIVE COATING TO PREVENT REACTION BETWEEN GRAPHITE SUSCEPTOR AND QUARTZ CRUCIBLE

(71) Applicant: SunEdison, Inc., St. Peters, MO (US)

(72) Inventors: Shailendra B. Rathod, St. Louis, MO (US); Richard J. Phillips, St. Peters, MO (US)

(21) Appl. No.: 14/141,101

(22) Filed: Dec. 26, 2013

Related U.S. Application Data
(60) Provisional application No. 61/747,020, filed on Dec. 28, 2012.

(51) Int. Cl. C30B 15/10; C09D 1/00

(52) U.S. Cl. CPC C30B 15/10; C09D 1/00
USPC 117/208; 156/293; 423/290; 423/440; 423/344; 423/326; 106/286.1; 106/286.4; 106/287.1

(57) ABSTRACT

A susceptor for supporting a crucible includes a body with an interior surface defining a cavity. A coating is disposed on the interior surface to provide a barrier for preventing contact between the body of the susceptor and the crucible disposed within the cavity.

### CROSS REFERENCE

This application claims priority to U.S. Provisional Application No. 61/747,020 filed Dec. 28, 2012, the disclosure of which is hereby incorporated by reference in its entirety.

### FIELD

This disclosure generally relates to systems and methods related to a protective coating between a graphite susceptor and a quartz crucible for preventing reaction between the graphite and quartz and increasing the lifetime of the susceptor.

### BACKGROUND

Single crystal silicon, which is the starting material for most processes for the fabrication of semiconductor electronic devices and solar cells, is commonly prepared by the so-called Continuous Czochralski (“CCz”) or Czochralski (“Cz”) methods. In these methods, polysilicon in the form of solid feedstock material is charged to a crucible and melted, a seed crystal is brought into contact with the molten silicon or a melt, and a single crystal is grown by slow extraction.

The quartz crucible is dimensionally unstable at the high temperature needed to melt the solid feedstock material. To prevent warping or deformation of the crucible, the crucible is supported by a graphite susceptor, which is dimensionally stable at the temperature required to melt the silicon feedstock material.

At this high temperature, the carbon from the graphite susceptor and the silica from the quartz crucible react with each other to generate oxidized carbon and silicon products in a gaseous form. The gaseous mixture generated by this reaction is then carried away from the area by an inert gas flowing around the susceptor and crucible. As the gaseous mixture is removed, more carbon and more silica surfaces are exposed, allowing further reaction and further consumption of the graphite susceptor. A cycle of erosion is repeated until the susceptor is no longer usable as a result of the loss of material.

A crucible is generally used for a single run, while the susceptor is generally used for multiple runs. However, due to this continuous cycle of erosion, the susceptor rapidly deteriorates, which decreases the useful lifetime of the susceptor. Thus, there is a need for a longer lasting susceptor.

This Background section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### BRIEF SUMMARY

A first aspect is a susceptor for supporting a crucible. The susceptor includes a body and a coating. The body has an interior surface that defines a cavity. The cavity is sized and shaped to be complementary to an outer size and shape of the crucible. The coating is on the interior surface and provides a barrier for preventing contact between the body of the susceptor and the crucible disposed within the cavity.

Another aspect is a method for providing a protective barrier to prevent carbon from a graphite structure from reacting with silica from a quartz structure at elevated temperatures. The method includes providing a graphite structure, a quartz structure that is at least partially shaped to rest against a surface of the graphite structure, and an inert material in the form of either a powder or suspended within a liquid. The inert material is applied to the surface of the graphite structure. The quartz structure is placed adjacent to the inert material on the surface of the graphite structure. The assembly of the quartz structure, the inert material, and the graphite structure are then heated.

Another aspect is a coating for providing a protective barrier between a graphite body of a susceptor and a quartz body of a crucible disposed within the susceptor during a crystal pulling process. The coating includes an inert material to inhibit a reaction between carbon of the susceptor and silica of the crucible. The inert material is inert with respect to both the carbon and the silica at the process conditions produced during the crystal pulling process.

Various refinements exist of the features noted in relation to the above-mentioned aspects. Further features may also be incorporated in the above-mentioned aspects as well. These refinements and additional features may exist individually or in any combination. For instance, various features discussed below in relation to any of the illustrated embodiments may be incorporated into any of the above-described aspects, alone or in any combination.

### BRIEF DESCRIPTION OF THE DRAWINGS

FIG. 1 is a cross sectional view of a crucible and a susceptor having a protective coating in accordance with one embodiment.

### DETAILED DESCRIPTION

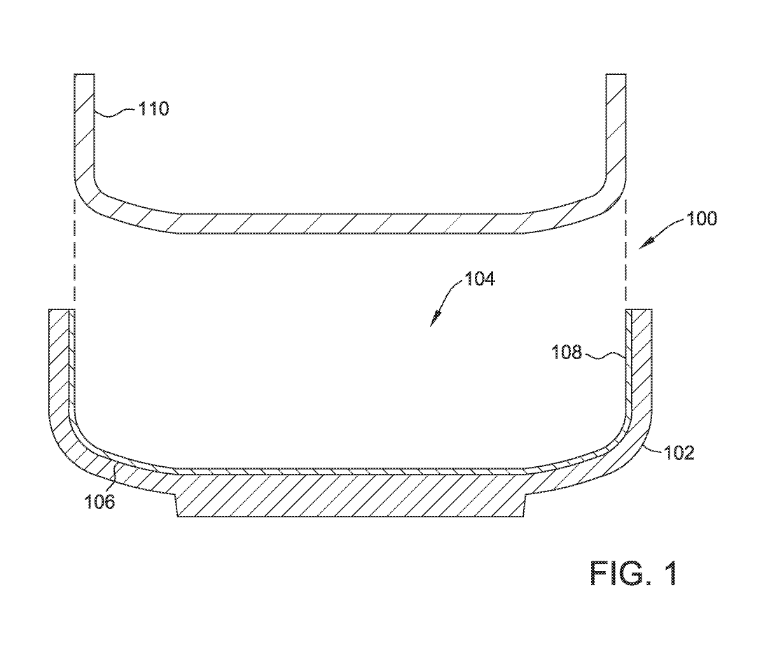

Referring to FIG. 1, a susceptor suitable for use in a crystal production or crystal puller system (not shown) for the production of crystal ingots is generally indicated at 100. The susceptor 100 includes a body 102 including an interior surface 106 that defines a cavity 104 sized and shaped to receive a quartz crucible 110 therein. Note the susceptor 100 may be used in any suitable crystal production or single crystal pulling system, though other uses of the susceptor are also contemplated within the scope of this disclosure.

During the crystal production process, the temperature around the crucible 110 is increased to a level at which the quartz is dimensionally unstable. Therefore, the quartz crucible 110 is placed within the graphite susceptor 100 to prevent the crucible from degrading, deforming or warping.

The interior surface 106 of the susceptor 100 has a protective coating 108 that prevents contact between the graphite of susceptor 100 and the quartz of crucible 110. The crucible 110 fits into and is supported by the coated interior surface 108 of the susceptor 100 during the production process.

The coating 108 includes an inert material that will inhibit or prevent a reaction between the carbon of the susceptor and the silica of the crucible. The coating 108 inhibits or prevents the direct contact of the graphite susceptor and the quartz crucible by providing a barrier that is inert with respect to both the carbon and the silica, e.g., under the processing conditions produced inside the crystal growth system.

The coating 108 may include such inert materials as, but not limited to, boron nitride (BN), silicon nitride (Si₃N₄),zirconium silicate (ZrSiO₄), tantalum carbide (TaC), molybdenum disilicide (MoSi₂), alloys containing MoSi₂, such as, but not limited to, MoSi₂—TiSi₂—Mo and MoSi₂—HfO₂—SiO₂. The coating 108 may be made by compacting the material into pellets or by suspending particles of the inert material in a solution. In this embodiment, the coating 108 is formed by directly brushing an inert material in the form of a powder onto the interior surface 106 of the graphite susceptor 100.

In another embodiment, the inert material is suspended within a liquid or a mixture of liquid having secondary materials such as, but not limited to, stabilizers, binders, and/or other suitable materials that form a coating or which are evaporated or reacted from the liquid suspension during application. The liquid with suspended inert materials may then be painted with a brush onto the interior surface 106 of the graphite susceptor 100. The formulation should not devitrify quartz or SiO.

A brushable Si₃N₄ solution may have a weight percentage of nitride powder in the range of about 5 to about 45. In one embodiment, a brushable Si₃N₄ solution for brushing onto the susceptor may have the following weight percentage: approximately 37.5% Si₃N₄, approximately 1.8% dispersant (e.g., Solsperse 20000), approximately 49.5% isopropyl alcohol (IPA), approximately 5.6% polyvinylbutyral (PVB), and approximately 5.6% polyethyleneglycol (PEG).

Brushable Si₃N₄ solution may be derived by first weighing out the IPA and PVB and then warming the IPA to approximately 26.67° C. (80° F.) in a covered container. The IPA may be stirred while it is being heated with a magnetic stirrer. Once the IPA reaches a temperature of approximately 26.67° C. (80° F.), the PVB is added to and mixed with the IPA using a high speed/high shear mixer until the fluid becomes transparent and no PVB flakes are present. The warm IPA and PVB mixture is then poured into a ball mill with Si₃N₄ milling media and the balance of the components (Si₃N₄, Dispersant, and then PEG). The mixture is mixed before the addition of each component.

The mixture is then milled for at least 2 hours. In some embodiments the mixture is milled for over 4 hours to mix the components. In other embodiments, the mixture is milled for at least 30 minutes followed by a filter process to remove agglomerates.

The solution may then be brushed directly onto the susceptor using applicators of foam knife edged brushes, which are not shreddable to prevent contamination of the fluid. The susceptor is typically not heated before use in a run, but the susceptor can be heated to a temperature where the solvents evaporate.

In still another embodiment, the coating includes a liquid having suspended inert materials that are sprayed onto the interior surface 106 of the graphite susceptor 108.

The brushable Si₃N₄ solution is too thick to be effectively sprayed from a pressurized spray gun. A sprayable Si₃N₄ solution suitably has a weight percentage of nitride powder in the range of about 5 to about 30. In one embodiment, a sprayable Si₃N₄ solution for use in a pressurized spray gun may have the following weight percentage: approximately 12.7% Si₃N₄, approximately 7.0% dispersant (e.g., Solsperse 20000), approximately 76.6% isopropyl alcohol (IPA), approximately 1.9% polyvinylbutyral (PVB), and approximately 1.9% polyethyleneglycol (PEG).

Sprayable Si₃N₄ solutions may be derived by first weighing out the IPA and PVB and then warming the IPA to approximately 26.67° C. (80° F.) in a covered container to expedite the solubilizing of the binder. The IPA may be stirred while it is being heated with a magnetic stirrer. Once the IPA reaches a temperature of approximately 26.67° C. (80° F.), the PVB is added to and mixed with the IPA using a high speed/high shear mixer until the fluid becomes transparent and no PVB flakes are present. The warm IPA and PVB mixture is then poured into a ball mill with Si₃N₄ milling media and the balance of the components (Si₃N₄, dispersant, then PEG). The mixture is mixed before the addition of each component.

The mixture is then milled for at least 2 hours. In some embodiments, the mixture is milled for over 4 hours to mix the components. In other embodiments, the mixture is milled for at least 30 minutes followed by a filter process to remove agglomerates.

The solution may then be brushed directly onto the susceptor using applicators of foam knife edged brushes, which are not shreddable to prevent contamination of the fluid. The susceptor is typically not heated before use in a run, but the susceptor can be heated to a temperature where the solvents evaporate.

The amount of dispersant in this solution and PEG are used to slow surface evaporation of the solvent in the sprayable case so that adequate solvent is removed by evaporation from bottom film layers. If the surface skins over too quickly, before adequate solvent has been evaporated from the film bulk, pinholes may result in the surface layer.

Advantages of using the presently disclosed coatings over grafoil strips include elimination of venting locations that allow the venting of gaseous products of the reaction between the carbon (C) from the graphite susceptor and the silica (SiO₂) from the quartz crucible that generate oxidized carbon (CO) and silicon products (SiO). (C₍ₛ₎+SiO₂₍ₛ₎→CO_{(g)}+SiO_{(g)}). Additional advantages include an increase in the lifetime of the susceptor without contamination of the contents of the crucible. The lifetime may be increased by at least 20% by sustaining better dimensional stability between the susceptor and the crucible during the crystal growth process, which results in a cost reduction and an increased throughput and yield. As the throughput and yield are increased, the ingot is produced more efficiently and at less cost.

When introducing elements of the present invention or the embodiment(s) thereof, the articles “a”, “an”, “the” and “said” are intended to mean that there are one or more of the elements. The terms “comprising”, “including” and “having” are intended to be inclusive and mean that there may be additional elements other than the listed elements. The use of terms indicating a particular orientation (e.g., “top”, “bottom”, “side”, etc.) is for convenience of description and does not require any particular orientation of the item described.

As various changes could be made in the above constructions and methods without departing from the scope of the invention, it is intended that all matter contained in the above description and shown in the accompanying drawing[s] shall be interpreted as illustrative and not in a limiting sense.

What is claimed is:

1. A susceptor for supporting a crucible, the susceptor comprising:
a body having an interior surface defining a cavity, the cavity having a size and shape complementary to an outer size and shape of the crucible; and
a coating on the interior surface, the coating providing a barrier for preventing contact between the body of the susceptor and the crucible disposed within the cavity.

2. The susceptor of claim 1, wherein the coating includes an inert material.

3. The susceptor of claim 2, wherein the inert material is selected from the group of boron nitride, silicon nitride, zirconium silicate, tantalum carbide, molybdenum disilicide, and molybdenum disilicide alloys.

4. The susceptor of claim 2, wherein the inert material is unreactive with quartz and graphite.

5. The susceptor of claim 1, wherein the susceptor is made of graphite.

6. The susceptor of claim 1 in combination with the crucible.

7. A coating for providing a protective barrier between a graphite body of a susceptor and a quartz body of a crucible disposed within a cavity of the susceptor during a crystal pulling process, the coating comprising:
an inert material to inhibit a reaction between carbon of the susceptor and silica of the crucible, the inert material being inert with respect to both the carbon and the silica at the process conditions during the crystal pulling process.

8. The coating of claim 7, wherein the inert material is selected from the group of boron nitride, tantalum carbide, silicon nitride, zirconium silicate, and molybdenum disilicide.

9. The coating of claim 7, wherein the inert material is a molybdenum disilicide alloy.

10. The coating of claim 9, wherein the molybdenum disilicide alloy is selected from the group of MoSi₂—TiSi₂—Mo and MoSi₂—HfO₂—SiO₂.

11. The coating of claim 7, wherein the inert material is in the form of a powder to be brushed onto an interior surface of the cavity of the susceptor.

12. The coating of claim 7, wherein the inert material is compacted into pellets.

13. The coating of claim 7, wherein particles of the inert material are suspended in a solution for painting onto an interior surface of the susceptor.

14. The coating of claim 13, wherein the solution includes a secondary material, the secondary material is selected from the group of stabilizers and binders.

15. The coating of claim 13, wherein the solution includes a secondary material that is one of evaporated and reacted from the solution during application of the inert material.

16. The coating of claim 7, wherein the inert material includes a nitride powder having a weight percentage in the range of about 5 to about 45.

17. A method for providing a protective barrier to prevent carbon from a graphite structure from reacting with silica from a quartz structure at elevated temperatures, the method comprising:
providing a graphite structure;
providing a quartz structure at least partially shaped to rest against a surface of the graphite structure;
providing an inert material in the form of one of powder and suspended within a liquid;
applying the inert material to the surface of the graphite structure;
placing the quartz structure adjacent the inert material on the surface of the graphite structure after application of the inert material to form an assembly; and
heating the assembly.

18. The method of claim 17, wherein the inert material is applied in the form of a powder or is suspended in a solution.

19. The method of claim 17, wherein the inert material is applied by one of brushing and spraying onto the graphite structure.

20. The method of claim 17, wherein the inert material includes a nitride powder having a weight percentage in the range of about 5 to about 45.
